(19) United States
(12) Patent Application Publication
(10) Pub. No.: US 2026/0271218 A1
(43) Pub. Date: Sep. 10, 2026

(54) COOLING DEVICE FOR COOLING ELECTRONIC COMPONENTS, USE THEREOF AND A METHOD FOR ITS PRODUCTION

(71) Applicant: SEMIKRON DANFOSS GMBH, Flensburg (DE)

(72) Inventors: Klaus Kristen OLESEN, Nordborg (DK); Lars PAULSEN, Nordborg (DK); Henning STRÖBEL-MAIER, Nordborg (DK)

(21) Appl. No.: 19/138,306

(22) PCT Filed: Dec. 12, 2023
(86) PCT No.: PCT/EP2023/085233

§ 371 Date: Jun. 12, 2025

(30) Foreign Application Priority Data
Dec. 13, 2022 (DE) 10 2022 133 174.1

(51) Int. Cl. H05K 7/20

(52) U.S. Cl. CPC H05K 7/20145; H05K 7/20163; H05K 7/20254; H05K 7/20272; H05K 7/20918; H05K 7/20927

(57) ABSTRACT

For efficient cooling of electronic components, in particular power electronics in an electric vehicle, cooling modules are provided with multiple cavities, each containing a flow-defining member formed as double-helix for two-way flow of coolant through the cavity.

### CROSS-REFERENCE TO RELATED APPLICATIONS

This application is a National Stage application of International Patent Application No. PCT/EP2023/085233, filed on Dec. 12, 2023, which claims priority to European Patent Application No. 102022133174.1, filed on Dec. 13, 2022, each of which is hereby incorporated by reference in its entirety.

### TECHNICAL FIELD

The present invention relates to cooling device for cooling electronic components, use thereof for an electric vehicle and a method for its production. In particular, it relates to a cooling device according to the preamble of the independent claim.

### BACKGROUND

In electric vehicles, the available power for propulsion is regulated in modules that contain power converters, switches, and regulators, which are subject to heating and which must be cooled in order to avoid damage. Especially during accelerations, electric vehicles, EV, need power in excess of 100 kW, and although only a small percentage of this power is converted to heat in the electronic power control system, the heat created in the electronic system can be as much as several kW, and with a local power density of more than 500 W/cm², which is substantial. To give an impression of this power, it is put forward that this power density is more than what a kitchen cooking plate produces. This heat has to be removed efficiently from the electronics in order to prevent damage by overheating. Accordingly, cooling of the electronics is a serious issue in EVs.

This issue is discussed in detail in U.S. Pat. No. 10,674,628, disclosing a cooling module for a power converter. For efficient cooling, this disclosure suggests series of identical coolant pipes that are provided side-by-side in a planar arrangement on a cooling plate that is abutting the electronics. Each coolant pipe is formed as a planar double spiral. It is explained in this disclosure that it creates an efficient cooling effect with improved uniform temperature distribution.

The system of U.S. Pat. No. 10,674,628 follows a traditional approach where thin pipes are used for transport of the coolant. Pipe systems for cooling of electronics reach back more than half a century, for example with reference to U.S. Pat. No. 4,161,980 for a double helical thyristor coolant capsule.

However, coolant pipe systems suffer from substantial friction through the tubing system, which reduces coolant flow, thus, going against the aim of efficient cooling.

An additional important aspect to take into account in relation to electric vehicles is the minimization of production costs. Pipes as coolant channels, especially where the pipes are provided as spirals or helices, is disadvantageous production-wise, as it implies a relatively slow and costly process. Accordingly, the systems in the disclosures U.S. Pat. No. 10,674,628 and U.S. Pat. No. 4,161,980, mentioned above, are not suitable for low-cost mass production.

Another approach for coolant channels is disclosed in Japanese patent application JP6268127A2 where a double-spiral coolant channel for cooling of electronics is provided in a block, thus, avoiding the production of pipes. However, despite the production-friendly approach as such, the long and thin coolant channel along the path through the block does not avoid the disadvantage of pressure loss in the channels which reduces flow and requires high pressure for high flow rates.

The prior art appears not to have solved the dilemma of providing uniform cooling with high coolant flow rates.

It would be desirable to provide a cooling system for electronics that do not have the disadvantages of the prior art.

### SUMMARY

It is therefore an objective of the invention to provide an improvement in the art. In particular, it is an objective to provide efficient cooling systems for electronics which are suitable for low-cost mass production, in particular in connection with electric vehicles. This objective and further advantages are achieved with a cooling device for cooling electronic components, its use and method of production, as described below and in the claims.

In short, for efficient cooling of electronic components, in particular power electronics in an electric vehicle, EV, cooling modules are provided with multiple cavities, each containing a flow-defining member formed as double-helix for two-way flow of coolant through the cavity.

The cooling device comprises a housing with a coolant inlet and a coolant outlet and a coolant flow path through the housing from the coolant inlet to the coolant outlet. The housing comprises a housing wall on which the electronics are provided and with which the electronics have thermal contact. The housing wall has an inner side in thermal contact with the coolant and an opposite outer side arranged for thermal contact with the electronic components for transfer of thermal energy from the electronic components through the housing wall and to the circulating coolant. Optionally, a similar arrangement with electronics is provided on a second, opposite wall of the housing.

The coolant flows through a first canal, which is a coolant supply canal and which is connected to the coolant inlet, and a second canal, which is a coolant drain canal and connected to the coolant outlet. The flow path for the coolant also comprises multiple, mutually separate coolant branches. Each coolant branch has a branch inlet connected to the coolant supply canal and a branch outlet connected to the coolant drain canal without being connected through any of the other of the multiple branches, thereby forming individual coolant circuits through each of the branches. The branches are distributed over the inner side of the housing for providing a homogeneous temperature profile in the housing wall and the electronics.

As already mentioned in the introduction, the heat created in the electronic system in an EV can be as much as several kW, and may have a local power density of more than 500 W/cm², which is substantial. In order for the electronics to be functioning properly and in order to avoid damage, this heat needs being removed efficiently. The following examples of configurations have proven efficient removal of heat. Furthermore, in order for multiple similar electronics working largely identical, the temperature for the various component should be identical, which requires that the temperature of the housing is kept homogeneous with a corresponding homogeneous heat removal across and along that part of the housing that is in thermal contact with the electronics. For this reason, multiple coolant branches are provided, each of which is removing heat from the wall.

For efficient heat removal, each branch comprises a cavity and a flow-defining member inside the cavity. For example, the cavities and their respective flow-defining members, which form of the multiple coolant branches, are arranged in parallel side-by-side, thus, covering a large area of the housing wall from which the heat is to be removed. For example, the housing is elongate with a longitude, and the cavities are arranged in parallel along a cavity orientation normal to the longitude. Optionally, the multiple branches are identical.

The flow-defining member comprises flow-defining walls that are arranged relatively to each other in a configuration causing an intermeshed double-helical or double quasi-helical flow path of the coolant through the cavity.

The term quasi-helical is used herein to describe a flow path that approximately resembles a helical path. It is pointed out that the wall members themselves need not necessarily be arranged as a helix, but they are arranged such that the resulting flow approximately follows a helical flow path. This does not necessarily imply that the flow path is circular helical, well knowing with reference to common knowledge and terminology in the relevant technical fields that the term square-helix and rectangular helix is well known and correspondingly understood by the skilled person. In this view, the term helical flow should be understood as a forward spiralling movement of the coolant, and, correspondingly, the term quasi-helical should be understood similarly as a forward spiralling movement of the coolant that approximates a helical movement, however, possibly implying some degree of distortions of a helix. Similar to helical motion, also the quasi helical motion of the coolant has a repetitive spiral movement along and about a central axis of the flow-defining member, which, in turn, typically coincides with a central longitudinal axis of the cavity that houses the flow-defining member.

The double helical or double quasi-helical flow path for the coolant along the flow-defining member through the cavity comprises a first flow path, which is a forward helical or quasi-helical flow path from the cavity inlet at a first end of the cavity to a second, opposite end of the cavity. At this end, the flow is reversed, and the coolant enters a second flow path, which is a return helical or quasi-helical flow path in opposite direction relative to the first flow path. The two helical or quasi-helical flow paths are intertwined, as is normally understood as such for a double helix.

In some embodiments, the coolant flows out of the cavity at the same end of the flow-defining member. This is the case of the coolant supply canal and the coolant drain canal for drain of the coolant after taking up heat are provided at the same end of the cavity.

However, it is also possible that the canals are provided at opposite ends of the cavities, for example parallel cavities. An option in this case is a third coolant flow path through a channel extending through the flow-defining member, for example a central channel, with a flow direction towards the second end of the cavity, from which the coolant is drained into the coolant drain canal. Alternatively, the flow-defining member comprises a third helical or quasi-helical flow path for the coolant in addition to the double-helical or double quasi-helical flow path and intertwined with the other two helices or quasi-helices for providing a triple-helical or triple quasi-helical flow path prior to the coolant flowing into the coolant drain canal at the second end of the cavity.

In some embodiments, the flow-defining member is formed as a screw and inserted into the respective cavity. However, production of members formed as a perfect mathematical helix, for example by moulding, is not possible due to the curving helical walls. In order to overcome this problem, the design and production of the flow-defining members has been adjusted so that the helix form is approximated into a generalised quasi-helix with straight sections, be it for a round quasi-helix or a rectangular quasi-helix.

In this sense, in some embodiments, the flow-defining member comprises multiple mutually parallel first straight wall sections and multiple mutually parallel second straight wall sections. The first straight wall sections are arranged on one side of a central sectional plane and the second straight wall sections on an opposite side of the central sectional plane. The first straight wall sections are angled relatively to the second straight wall sections such that the first and second straight wall sections are crossed relatively to each other at the central sectional plane. When the straight walls from both side are projected onto the central sectional plane, it resembles a zigzag path. Pairs of first straight wall sections on the first side of the central sectional plane and pairs of second straight wall section on the second side of the central sectional plane forms corresponding segment of the flow path for the coolant. As the flow segments are arranged on both sides of the central sectional plane, they cause an alternating flow of the coolant from the first side to the second side of the central sectional plane and then back again to the first side during a forward movement along an axis of the flow-defining member.

For the quasi-helical flow path, the flow follows a first forward directed flow path segment along and between a pair of the first straight wall sections on the first side of the central sectional plane, then through the central sectional plane, and then further forward along and between a pair of the second straight wall sections on the second side of the central sectional plane before flowing back again to the first side through central sectional plane for similar consecutive forward flow path segments. This arrangement of flow path segments, although the segments are straight, causes a forward spiralling movement of the coolant through the cavity, hence, resulting in the aforementioned quasi-helical flow of the coolant.

As the flow-defining member causes a double quasi-helical flow path, a similar arrangement of flow path segments are arranged for the return flow along the flow-defining member towards the first end of the cavity. The Forward flow path and the return flow path are intermeshed.

For ease of production, the flow-defining straight wall sections for the flow-defining member are attached to a frame in order to form a module. This module inserted into parts that form walls of the housing, for example in a sandwich manner. Typically, the frame contains the central sectional plane and is parallel therewith.

Advantageously, the flow-defining walls sections for multiple flow-defining members are attached to the frame such as to form a module with an array of flow-defining members oriented in parallel side-by-side. Optionally, all flow-defining members are identical, which eases production.

In some embodiments, the housing comprises two opposite parts, one part comprises the housing wall and is provided on one side of the module and a second part is provided on a second, opposite side of the module, the two parts in combination with the module providing a fluid tight housing apart from the coolant inlet and the coolant outlet.

Optionally, the frame forms part of an inner wall of the final cavity in which the flow-defining member is provided.

In some embodiments, useful for low-cost mass production, the module comprises a first array plate that comprises the first straight sections, a second array plate that comprises the second straight sections, and a central plate containing the central sectional plane and being parallel therewith. The plates are combined with the central plate sandwiched between the first and second array plate. The central plate comprises multiple passages, each of the multiple passage connecting one of the first flow path segments formed by a pair of the first straight wall sections on a first side of the central plate to one of the second flow segments formed by a pair of the second straight sections on a second, opposite side of the central plate. For example, each passage comprises a portion of the cavity wall.

For some of the embodiments, in particular, the following production method is useful. A planar frame and a flow-defining member that is solidly attached to the frame in a cavity portion of the frame is formed in a forming process. In a later assembly process, a thermally conducting plate is provided on either side of the frame, enclosing the frame and the flow-defining member between the plates in a sandwich-construction. The frame in combination with the plates form a fluid-tight cavity around the flow-defining member apart from a coolant inlet and a coolant outlet for flow of coolant into the cavity, then along a first and second flow path determined by the flow-defining member and then out of the cavity. The flow-defining member comprises flow-defining walls, as already discussed above, causing the aforementioned intermeshed double-helical or double quasi-helical flow path of the coolant through the cavity for flow of coolant along the first flow path, which is a forward helical or quasi-helical flow path from the cavity inlet at a first end of the cavity to a second, opposite end of the cavity, where the flow is reversed for the coolant to enter the second flow path, which is a return helical or quasi-helical flow path in opposite direction relative to the first flow path, prior to flow of the coolant out of the cavity through the coolant outlet.

For example, the forming process comprises a stamping process including removal of some portions of a metal sheet for providing cavity portions within the frame and including deformation of other portions of the metal sheet for providing the flow-defining walls. Typical thickness dimensions of the metal sheet are 1-5 mm. Alternatively, the forming process comprises moulding or sintering. These methods are useful in particular, if the planar frame and the flow-defining member are formed as a combination in a single material.

In particular, such forming and assembly processes are useful for low-cost mass production if the frame and the flow-defining member are parts of an array of frames and flow-defining members formed in the forming process, in particular, if the frames and the flow-defining members in the array identical.

With reference to the above, optionally, the forming process for the array comprises forming a first array plate that comprises first straight mutually parallel sections and forming a second array plate that comprises second straight mutually parallel sections and forming a central plate with multiple coolant passages, and sandwiching the central plate between the first and second array plates. In particular, the method comprises providing the first straight sections angled relatively to the second straight sections such that the first and second straight sections are crossed relatively to each when projected onto the central plate. In this case, each pair of straight first sections and each pair of second sections forms a flow path segment for the helical or quasi-helical flow path of the coolant through the cavity, wherein each of the multiple passages in the central plate is connecting one of the first flow path segments formed by pairs of first straight sections on a first side of the central plate to one of the second flow segments formed by pairs of the second straight sections on the second, opposite side of the central plate. Optionally, each passage comprising a portion of the cavity wall. The flow segments are arranged alternating between the first and second side of the central plate for flow of coolant alternatingly between the first and the second side of central plate, with a first flow path segment along one of the first straight sections on the first side of the central plate, then through the central plate and along one of the second straight sections on the second side of the central plate before flowing back aging to the first side through central sectional plane for similar consecutive flow path segments, resembling a quasi-helical flow path.

The cooling device is useful in particular for cooling power electronics in an electric vehicle (EV), for example cooling power modules, converters and/or inverters.

For example, electronic components comprise a power module including semiconductor switches, such as Insulated Gate Bipolar Transistors (IGBT) or wide-bandgap Silicon Carbide (SiC) or GaN semiconductor switches mounted on a substrate.

Optionally, the substrate, comprises an insulating base with conducting tracks to form the circuitry required, attached to the insulating base. Examples of suitable substrates include AMB (active metal braze) substrates formed of two conducting copper layers on either side of an insulating ceramic layer. Examples of other suitable substrates are DBA (direct bonded aluminium) or DBC (direct bonded copper).

With respect to cooling possible electronics on the first wall of the housing, optionally also on the opposite, second wall of the housing, the following exemplary dimensions, coolant flow rates, temperatures of the electronics, are set forth.

Dimensions of the cavities are in the range of 3-15 mm with respect to length and 1-4 mm with respect to width.

For the flow-defining members, the number of straight wall sections is in the range of 4-20.

Thickness dimensions of the straight wall sections are typically in the range of 0.5-2 mm.

En example of the number of cavities in an array is in the range of 3-20.

Typical thicknesses of the array frame are in the range of 0.8-3 mm

Simulations have illustrated that a temperature homogeneity of DT<1K can be achieved for electronics that comprise three half-bridge modules, where each module comprises 4-12 semiconductor chips. This temperature homogeneity is substantially better than a typical pin fin cooler, which has DT in the range of 10-15K under typical load conditions.

Typical dimensions of the cooling device are 150-250 mm×35-60 mm×6-15 mm for automotive applications.

Typical dimensions of a cooling device, for example as shown in FIG. 17, when used for a personal car electric vehicle, are approximately 200 mm×60 mm×12 mm.

For renewable energy applications, such as the power electronics in wind turbines where several MW are processed or off-road electric vehicles for example mining the cooling device dimension will be on the order of 400-800 mm×200-400 mm×20-40 mm.

### BRIEF DESCRIPTION OF THE DRAWINGS

The invention will be explained in more detail with reference to the drawing, where

FIG. 1 illustrates a basic principle of a cooling module with double helical flow path;

FIG. 2 illustrates flow through a double helical flow-defining member;

FIG. 3 is a sketch of a housing;

FIG. 4 illustrates a housing with electronic on its outer side;

FIG. 5 is a cross section through a flow-defining member in a cavity;

FIG. 6 illustrates an option of coolant flow through a housing;

FIG. 7 A shows a longitudinal cross section through the housing along a central plane and FIG. 7B is an enlarged section thereof;

FIG. 8 illustrates a flow-defining member in a double helix structure with straight walls sections having rounded wall-edges in A) perspective view, B) side view and C) side view under an angle;

FIG. 9 illustrates an array of multiple flow-defining members;

FIG. 10 illustrates an array of multiple flow-defining members in two opposite halves of a housing in which half-cavities are formed;

FIG. 11 illustrates a transverse cross section through the housing;

FIG. 12 illustrates a longitudinal cross section through the housing for double-helical flow-defining members having round wall edges;

FIG. 13 illustrates a longitudinal cross section through the housing for double-helical flow-defining members having straight wall edges;

FIG. 14 illustrates a flow-defining member in a double helix structure with straight walls sections having straight wall-edges in A) perspective view, B) side view and C) side view under an angle;

FIG. 15 illustrates an array of multiple flow-defining members of the type as in FIG. 14;

FIG. 16 A) illustrates the cross sectional central plane in the array of FIG. 15 and FIG. 16B is an enlarged section thereof;

FIG. 17 is an exploded view of a housing with section of arrays of flow-defining members;

FIG. 18 is an exploded view of a partially assembled housing with section of arrays of flow-defining members.

### DETAILED DESCRIPTION

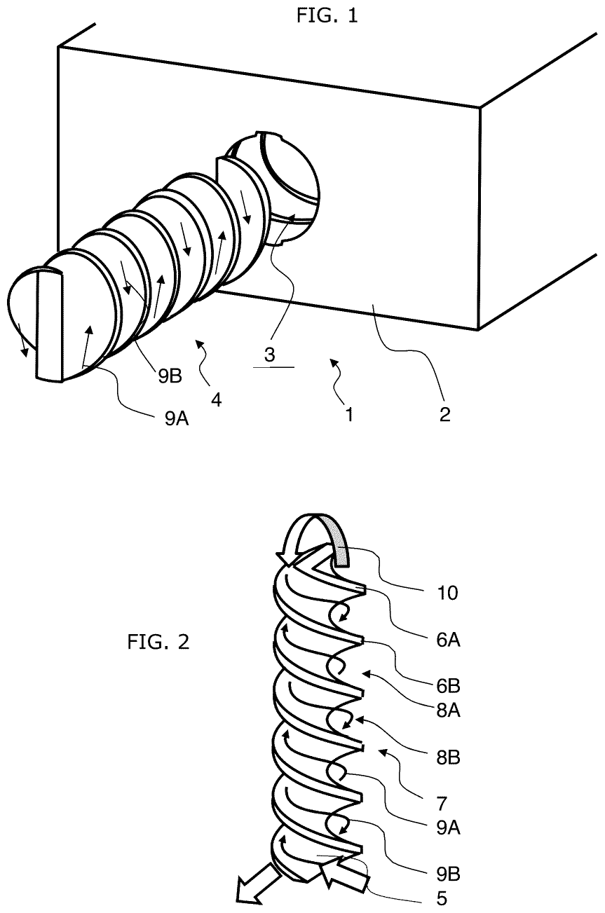

FIG. 1 illustrates some basic principles that are used for embodiments of the invention. A cooling module 1 comprises a housing 2 in which a cavity 3 is provided. The cavity 3 is used for flow of coolant through the cavity 3 for removing heat from the housing 2. The flow path of the coolant in and out of the housing 2 is determined by a flow-defining member 4 that is inserted into the cavity 3. As illustrated in FIG. 1 and further in FIG. 2, the flow-defining member 4 is exemplified as a double helical screw with a central part 5 around and along which two intertwined helical walls 6A, 6B extends forming double-helix windings of the screw-shaped portion 7 of the flow-defining member 4. The two intertwined helical walls 6A, 6B comprise a first helical flow path 8A, the direction of which is indicated by arrow 9A, for forward flow of coolant, and a second helical flow path 8B, the direction of which is indicated by arrow 9B, for return flow of coolant, after the coolant has changed direction of flow from forward to rearward at the closed end of the cavity, which is indicated by the curved arrow 10.

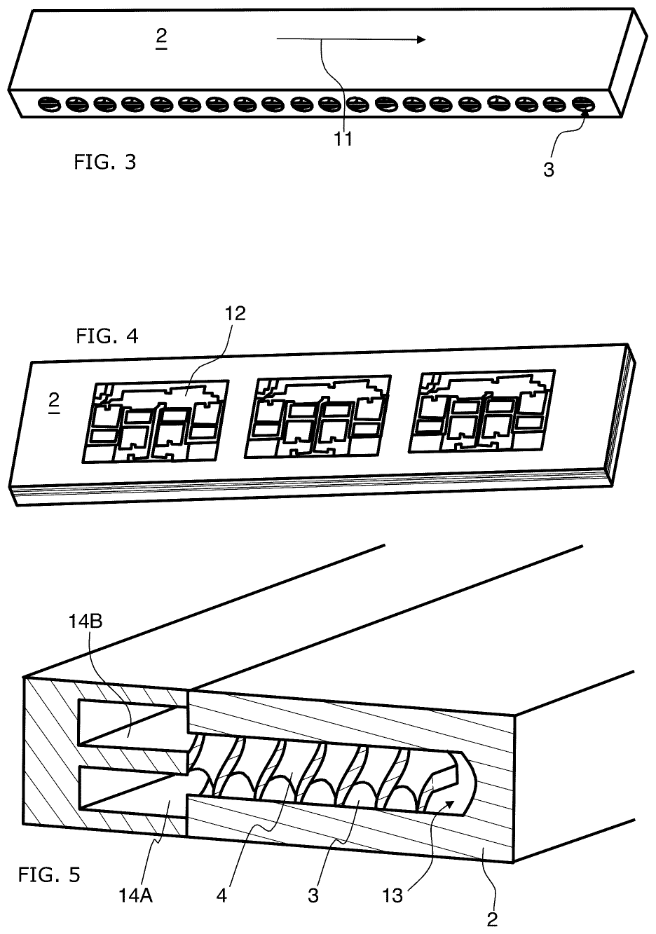

For practical use, in order to provide a large area with uniform cooling, the housing 2 has not only a single such cavity 3 with flow-defining member 4, but the housing 2 has multiple cavities 3, for example distributed along the longitude 11 of the housing, as illustrated in FIG. 3. Providing multiple of such parallel cavities 3 side-by-side along the longitude 11 of the elongate housing 2 and oriented laterally to the longitude 11 provides the necessary approximately uniform removal of heat from the outer surface of the housing 2 by heat transfer through the heat-conductive wall material of the housing 2.

As illustrated in FIG. 4, electronic components 12 are arranged on the outer side of the housing 2 in thermal contact with the housing 2 surface for heat transfer of the electronic components 12 to the housing 2 and through the housing 2 material into the coolant that is flowing in and out of the cavities 3.

FIG. 5 shows cross section along a cavity 3 in which a flow-defining member 4, shaped as a double helical screw, is provided. Clearly seen is the closed end 13 of the cavity 3 where the direction of the coolant is reversed. Lateral to the cavities 3 extend two canals 14A, 14B, of which a first canal, which is a coolant supply canal 14A, is used for supply of coolant into the cavities 3, and a second canal, which is a coolant drain canal 14B, is used for drain of coolant from the cavities 3 after the coolant has received thermal energy from the electronic components through the wall of the housing 2.

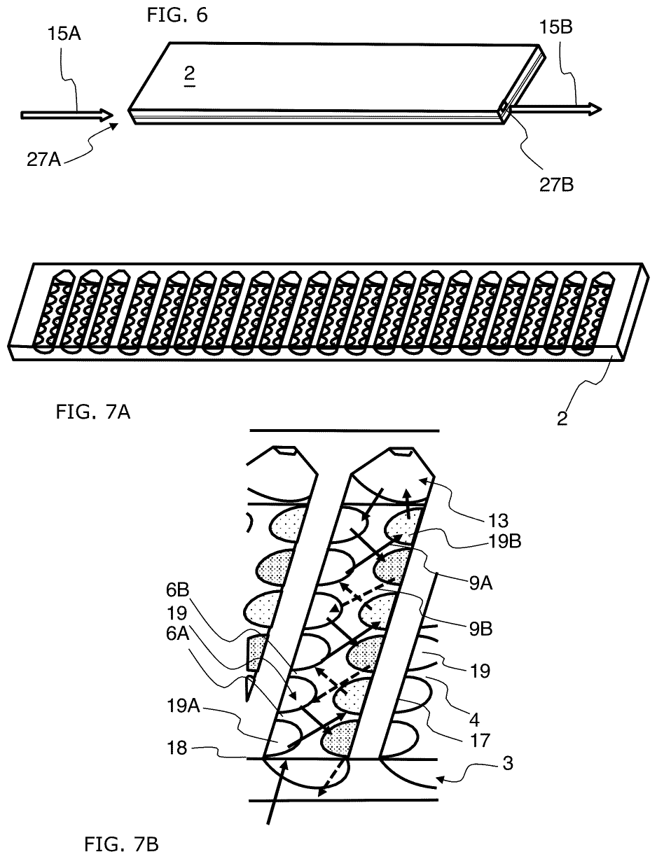

FIG. 6 illustrates by arrow 15A the entrance of coolant through a coolant inlet 27A into the coolant supply canal 14A and by arrow 15B exit of the heated coolant through the outlet 27B.

FIG. 7A is a perspective sectional view into the lower half of the housing 2. FIG. 7B shows an enlarged section of FIG. 7A for better understanding. Arrows 9A, 9B, similar to the arrows in FIG. 1 and FIG. 2, indicate flow directions, with the stippled arrows indicating the flow direction in the lower half of the housing 2, underneath the central sectional plane 18, and solid arrows illustrate the flow direction above the central sectional plane 18.

From this sectional illustration, the double helical flow path crossing through the central sectional plane 18 appears as a plurality of passages 19 in the central sectional plane 18, where each passage 19 is delimited by the two intertwined helical walls 6A, 6B of the flow-defining member 4 and the wall 17 of the cavity 3. The portion of the flow paths above and below central sectional plane 18 are formed by the two intertwined helical walls 6A, 6B and the wall 17 of the cavity 3, and these sections are connecting the illustrated passages 19 in a pattern that resembles a zig-zag pattern in the projection onto the central sectional plane 18, as illustrated. Each passage 19, apart from the passages 19A, 19B at the opposite ends of the flow-defining member 4, are connecting one channel section under the central sectional plane 18 with one channel section above the sectional plane 18.

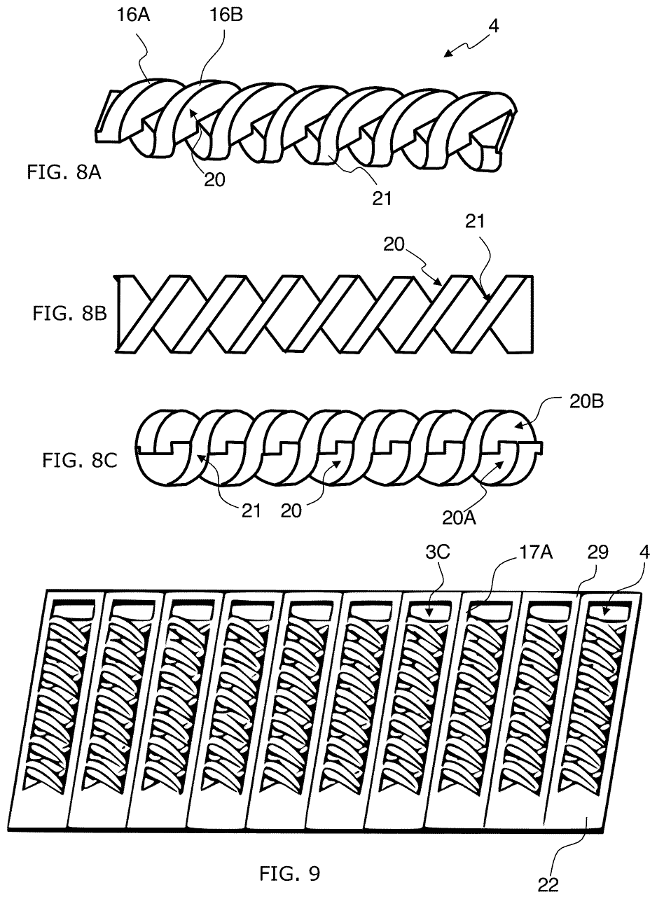

In some further embodiments, this principle has been generalised to structures where a double helical flow path is approximately maintained, but where the two intertwined helical walls 6A, 6B are substituted by walls 16A, 16B that are easier to manufacture. An example is illustrated in FIGS. 8A, 8B, and 8C, where a flow-defining member 4 with a quasi-helical flow path is illustrated, resembling an approximate screw shape but with walls 16A, 16B having straight sections 20 connected by curved sections 21 resembling a twist of the wall portions. As observed, in this generalised example, the walls 16A, 16B are not constantly curving along a helix but have straight first wall sections 20A on a first side of the central sectional plane and second straight wall sections 20B on a second, opposite side of the central sectional plane 18 in zig-zag form and interconnected by the curving/twisting sections 21.

An advantage is that these structures can be made by moulding or by compression of powder material, such as sintering of ceramics, for example metal-ceramics. Alternatively, a sheet forming process is used where metal sheets are stamped between templates for providing openings and deformed sections.

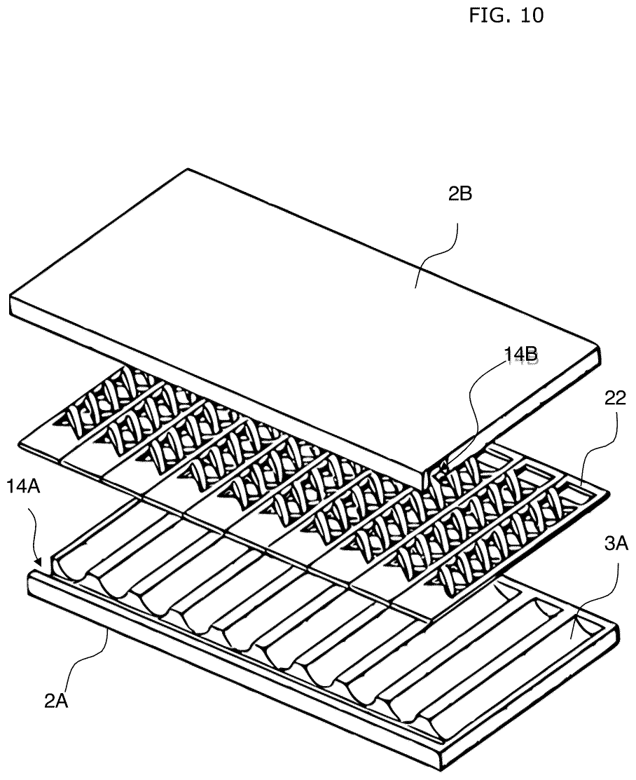

This manufacturing technique also implies that not only single flow-defining members 4 for insertion into single cavities 3 can be produced by cost efficient and quick production methods, but arrays of multiple of such flow-defining members 4 can be produced in a single manufacturing step, optionally as part of an array module 22 including frames 29 with a wall-portion 17A of the cavities 3 at the central sectional plane, as illustrated in FIG. 9.

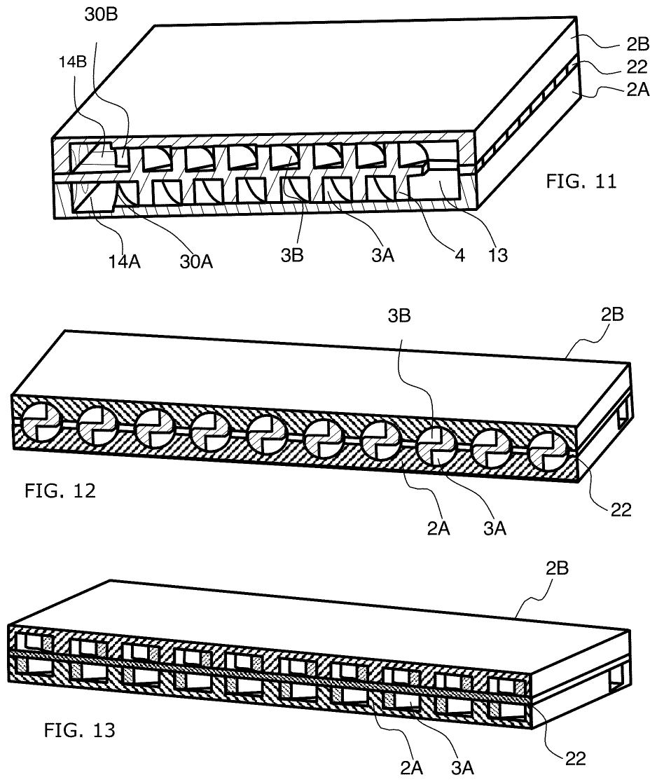

This array module 22 comprising the flow-defining members 4 is then inserted into two correspondingly shaped shells 2A, 2B of the housing 2, each shell 2A, 2B comprising a corresponding array of cavities portions 3A, 3B, see also FIG. 11 for illustration of the cavity portions 3A, 3B. Once assembled, the two shells 2A, 2B of the housing 2 are pressing the cavities portions 3A, 3B of the shells 2A, 2B against the array module 22, and the cavity portions 3A, 3B of the shells 2A, 2B in combination with the cavity portion 3C of the frames 29 close the cavities 3 in a tight manner, so that coolant does not flow from one cavity 3 to a neighbouring cavity 3. Notice that the flow path for the coolant, despite this more generalised screw form, approximately resembles a double quasi-helical flow path.

FIG. 11 shows a lateral cross section of the arrangement of FIG. 10, once assembled. It illustrates the cavity 3 as well as the cavity portions 3A, 3B in the shells 2A, 2B and the flow-defining member 4 as well as the end 13 of the cavity 3 where the coolant changes direction from the forward direction in the first quasi-helical flow path to the rearward direction in the second quasi-helical flow path. Similar to FIG. 5, FIG. 11 also shows the coolant supply canal 14A and the coolant drain canal 14B.

A longitudinal cross section thereof is illustrated in FIG. 12, showing the circular cross section of the cavities 3, comprising a lower cavity portion 3A, which was also illustrated in FIG. 10, and an upper cavity portion 3B.

Whereas the cavities 3 in FIG. 10 in the housing 2 have cylindrical form with circular cross section, as illustrated in FIG. 12, the principle can be generalised even further to cavity shapes having other cross section, for example cavities with rectangular cross section, as illustrated in FIG. 13, implying a rectangular double quasi-helical flow path.

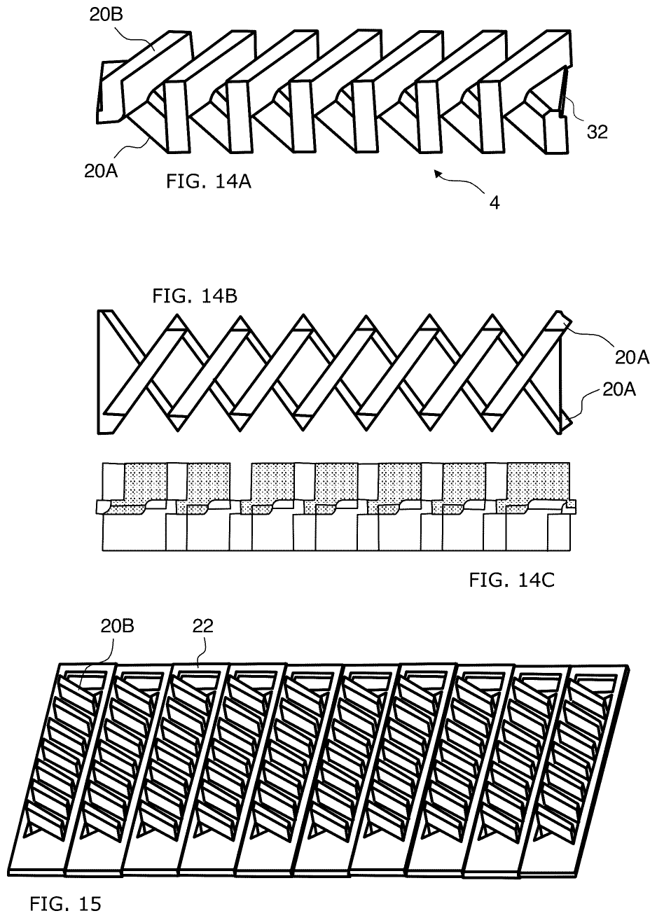

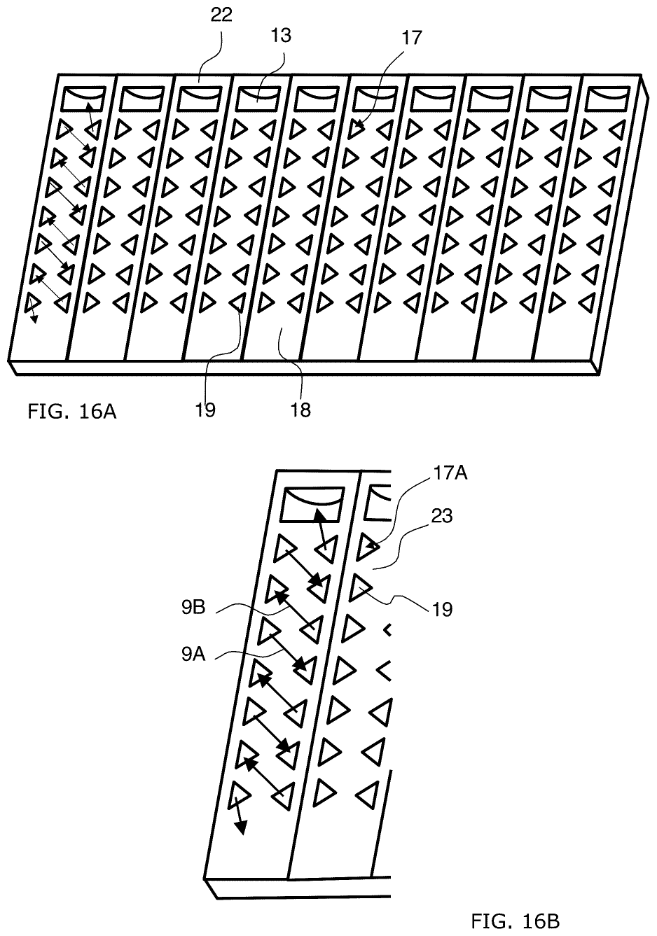

For use in such cavities with rectangular cross section, FIGS. 14a, 14B, and 14C illustrates a possible flow-defining member 4, which are shown in FIG. 15 in array form provided in an array module 22. Each of these flow-defining members 4 comprises straight wall sections 20A, 20B arranged in a zig-zag path with mutually parallel straight first wall sections 20A, forming an upper half of a rectangular double quasi-helical flow path above the central sectional plane 18, and mutually parallel straight second wall sections 20B, forming a lower half of a rectangular double quasi-helical flow path below the central sectional plane 18. The first wall sections 20A and the second wall sections 20B cross each other when projected onto the central sectional plane 18 and are arranged alternatingly below and above the central sectional plane 18. The cross sectional plane is illustrated in FIG. 16A. The first wall sections 20A and the second wall sections 20B are provided in two sets that form a rectangular double quasi-helical flow path for the coolant, in principle similar to the double helical flow path illustrated in FIGS. 1 and 2.

Due to the first and second wall sections 20A, 20B being offset with opposite angles alternatingly below and above the central sectional plane 18, as also illustrated in the array module in FIG. 15, the passages 19 in the central sectional plane 23 are formed triangular, each triangle formed by first and second wall sections 20A, 20B and the cavity wall portion 17A of the cavity 3. The triangular shape of the passages 19 is different from the semi-circular passages 19 illustrated in FIG. 7B. Notice in FIG. 16B, which is an enlarged cross section of FIG. 16A, the flow direction between the passage 19 above the central sectional plane 23 is indicated by arrows 9A, 9B, similar to the indications in FIG. 7B.

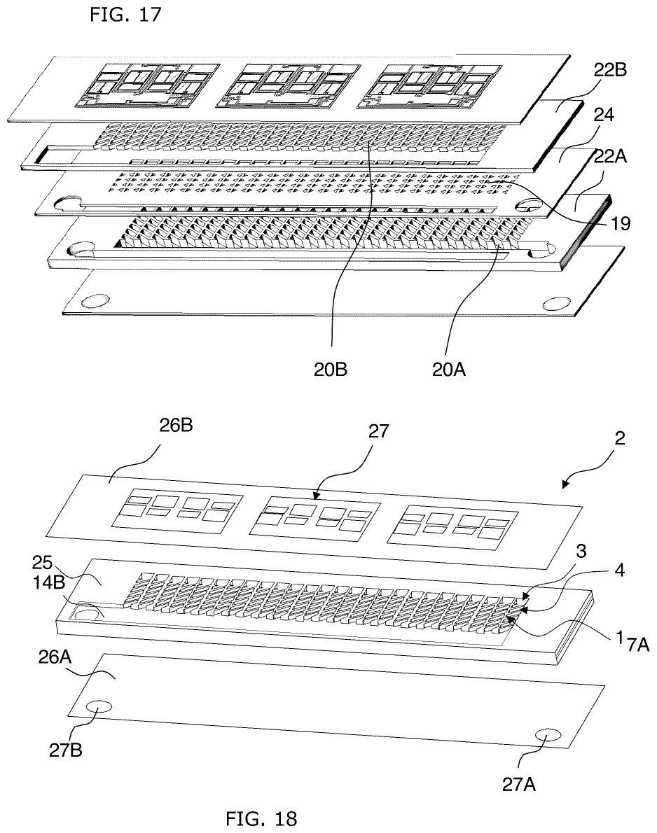

Taking offset in the shape of the flow-defining members 4 that are illustrated in FIG. 15, it is also possible to produce such flow-defining members 4 in layers, as illustrated in the embodiment of FIG. 17, with a central plate 24 that defines only the passages 19 of the central plane 23, which was shown in FIG. 16A and FIG. 16B, and a first formed array plate 22A with first wall sections 20A on one side of the central plate 24 for defining the flow on that side of the central plate 24, which is exemplified as the lower side of the central plate 24, and a second formed array plate 22B with second wall sections 20B on the opposite side of the central plate 24, which is exemplified as the upper side of the central plate 24. The second wall sections 20B are angled relatively to the first wall sections 20A similar to the configuration of FIG. 14 and FIG. 15. When assembling the first formed array plate 22A with the central plate 24 and the second formed array plate 22B, an array of flow-defining members 4 is achieved similar to the illustration of the array module in FIG. 15.

For each of the passages 19 in the central plate 24, other than the passages 19A, 19B at the ends of the cavities 3 (reference is made to FIG. 7B for the end cavities 19A, 19B), the first wall sections 20A in the first formed array plate 22A connects below the central plate 24 the corresponding passage 19 with a first neighbouring passage 19 below, and the second wall sections 20B in the second formed array plate 22B connects above the central plate 24 the same corresponding passage 19 with a second neighbouring passage in the central sectional plane 18. This way, a zig-zag flow path alternating below and above the central plate 24 is provided, resulting in a double quasi-helical flow path for the coolant.

Similar to the example in FIGS. 1 and 2, in combination, the flow paths sections formed by pairs of straight first wall sections 20A and pairs of straight second wall sections 20B are arranged to provide a double quasi-helical flow path by the flow-defining member 4, analogous to the example in FIG. 7B. This is so, irrespective of the flow-defining member 4 not being produced as a monolithic separate element and then inserted into a cavity 3, as initially explained in relation to FIG. 1, but due to production simplicity where the flow-defining member 4 is combined with frames comprising portions 17A of the cavity walls 17 during production, following the approach introduced in FIG. 9 and followed further in FIG. 15 and even further matured in FIG. 17.

The central plate 24 of FIG. 17 is combined with the first formed array plate 22B and the second formed array plate 22B into a module 25, as illustrated in FIG. 18, for example by pressing, brazing, gluing, or welding, such as laser welding. The module 25 comprises the array of flow-defining-members 4, including separating walls forming portions 17A of cavity walls between the flow-defining members 4, where the cavity walls are closed, once, the housing 2 is completed by closure using top plate 26B and bottom plates 26A, as illustrated in FIG. 18. The module 25 can also be manufactured as one monolithic part by forging (impact extrusion) in which case the forming of the communicating holes of plate 24 (FIG. 17) may require a subsequent drilling or stamping operation.

As illustrated in FIG. 17 and FIG. 18, electronic components 13 are abutting and in thermal contact with at least one side of the housing 2 for conduction of heat from the electronic components 13 through the wall of the housing 2 and into the coolant flowing inside the cavities 3 inside the housing.

Optionally, and as illustrated in FIG. 18, the coolant inlet 27A and coolant exit 27B, correspondingly connected to the coolant supply canal 14A and the coolant drain canal 14B, see also FIG. 5 and FIG. 11 in comparison, are provided in the bottom plate 26A, which is a slightly different arrangement as compared to the embodiment in FIG. 6 and FIG. 10, where the coolant inlet and the coolant outlet were provided in opposite end faces of the elongate housing 2.

While the present disclosure has been illustrated and described with respect to a particular embodiment thereof, it should be appreciated by those of ordinary skill in the art that various modifications to this disclosure may be made without departing from the spirit and scope of the present disclosure.

What is claimed is:

1. A cooling device for cooling electronic components, the cooling device comprising a housing with a coolant inlet and a coolant outlet and a coolant flow path through the housing from the coolant inlet to the coolant outlet, wherein the housing comprising a housing wall having an inner side in thermal contact with the coolant and an opposite outer side arranged for thermal contact with the electronic components for transfer of thermal energy from the electronic components through the housing wall and to the coolant; wherein the coolant flow path comprises a coolant supply canal connected to the coolant inlet, and a coolant drain canal connected to the coolant outlet, as well as multiple, mutually separate coolant branches, each branch having a branch inlet connected to the coolant supply canal and a branch outlet connected to the coolant drain canal without being connected through any of the other of the multiple branches, thereby forming individual coolant circuits through each of the branches; wherein the branches are distributed on the inner side of the housing wall for providing a homogeneous temperature profile in the housing wall and the electronic components, wherein each branch comprises a cavity and a flow-defining member inside the cavity, wherein the flow-defining member comprises flow-defining walls arranged for causing an intermeshed double-helical or double quasi-helical flow path of the coolant through the cavity for flow of coolant along a first flow path, which is a forward helical or quasi-helical flow path from a cavity inlet at a first end of the cavity to a second, opposite end of the cavity, where the flow is reversed for the coolant to enter a second flow path, which is a return helical or quasi-helical flow path in opposite direction relative to the first flow path, prior to flow of the coolant into the coolant drain canal.

2. The cooling device according to claim 1, wherein the cavities and their respective flow-defining members of the multiple coolant branches are arranged in parallel side-by-side.

3. The cooling device according to claim 2, wherein the housing is elongate with a longitude, and wherein the cavities are arranged in parallel along a cavity orientation normal to the longitude.

4. The cooling device according to claim 1, wherein the flow-defining walls of the flow-defining member comprise multiple straight mutually parallel first wall sections and multiple mutually straight parallel second wall sections, wherein the first wall sections are arranged on one side of a central sectional plane and the second wall sections on an opposite side of the central sectional plane, wherein the first wall sections are angled relatively to the second wall sections such that the first and second wall sections are crossing each other at the central sectional plane, wherein pairs of first wall sections and pairs of the second wall sections form segments of the flow path for the coolant, wherein the flow segments are alternating between the first and second side of central sectional plane, with a first flow path segment along a pair of first wall sections on the first side of the central sectional plane, then through the central sectional plane and along one pair of the second wall sections on the second side of the central sectional plane before flowing back aging to the first side through the central sectional plane for similar consecutive flow path segments.

5. The cooling device according to claim 4, wherein the flow-defining walls of the flow-defining member are attached to a frame to form a module that comprises part of an inner wall of the cavity in which the flow-defining member is provided.

6. The cooling device according to claim 5, wherein the frame contains the central sectional plane and is parallel therewith.

7. The cooling device according to claim 5, wherein the flow-defining first and second wall sections for multiple flow-defining members are attached to the frame such as to form a module with an array of multiple flow defining members oriented in parallel side-by-side.

8. The cooling device according to claim 7, wherein the housing comprises two opposite parts, one part comprising the housing wall and provided on one side of the module and a second part comprising a further housing wall provided on a second, opposite side of the module, the two parts in combination with the module providing a fluid tight housing apart from the coolant inlet and the coolant outlet.

9. The cooling device according to claim 8, wherein the module comprises a first array plate that comprises the first wall sections, a second array plate that comprises the second wall sections, and a central plate containing the central sectional plane and being parallel therewith, wherein the central plate is sandwiched between the first and second array plates and comprises multiple passages, each of the multiple passage connecting one of the first flow path segments formed by the first wall sections on a first side of the central plate to one of the second flow segments formed by the second wall sections on a second, opposite side of the central plate.

10. The cooling device according to claim 1, wherein the multiple cavities and flow-defining members are identical.

11. The cooling device according to claim 1, wherein the coolant inlet canal and the coolant outlet canal are provided at opposite ends of the cavities, wherein the cavities are oriented in parallel to each other, and wherein each of the flow defining members comprises a third flow path downstream of the second flow path and towards the second end of the cavity, wherein the third flow path is a third helical or quasi-helical flow path in addition to and intertwined with the double-helical or double quasi-helical flow path and arranged for providing a triple-helical or triple quasi-helical flow path for flow prior to coolant flow into the coolant drain canal.

12. A cooling device according to claim 1 in combination with electronic components provided on the first wall of the housing.

13. Use of a cooling device according to claim 1 in an electrical vehicle for cooling electronic components used for power regulation of electrical propulsion motors.

14. A method of producing a cooling device according to claim 1, the method comprising, forming in a forming process a planar frame and a flow-defining member that is solidly attached to the frame in a cavity portion of the frame, providing in an assembly process a thermally conducting plate on either side of the frame, and enclosing the frame and the flow-defining member between the plates in a sandwich-construction; wherein the frame in combination with the plates form a fluid-tight cavity around the flow-defining member apart from a cavity inlet and a cavity outlet for flow of coolant from the coolant supply canal through the coolant inlet into the cavity, then along a first and second flow path determined by the flow-defining member and then through the cavity outlet out of the cavity into the coolant drain canal; wherein the flow-defining member comprises flow-defining walls causing an intermeshed double-helical or double quasi-helical flow path of the coolant through the cavity for flow of coolant along the first flow path, which is a forward helical or quasi-helical flow path from the cavity inlet at a first end of the cavity to a second, opposite end of the cavity, where the flow is reversed for the coolant to enter the second flow path, which is a return helical or quasi-helical flow path in opposite direction relative to the first flow path, prior to flow of the coolant out of the cavity through the coolant outlet.

15. The method according to claim 14, wherein the forming process comprises a stamping process including removal of some portions of a metal sheet for providing cavity portions within the frame and including deformation of other portions of the metal sheet for providing flow-defining wall sections or wherein the forming process comprises moulding or sintering.

16. The method according to claim 14 wherein the frame and the flow-defining member are formed as a combination in a single material.

17. The method according to claim 14, wherein the frame and the flow-defining member are parts of an array of frames and flow-defining members formed in the forming process.

18. The method according to claim 17, wherein the method comprises forming the frames and the flow-defining members in the array identical, a first array plate that comprises the first wall sections, a second array plate that comprises the second straight wall sections, and a central plate containing the central sectional plane and being parallel therewith, wherein the central plate is sandwiched between the first and second array plates and contains multiple passages, each of the multiple passage connecting one of the first flow path segments formed by the first wall sections on a first side of the central plate to one of the second flow segments formed by the second wall sections on a second, opposite side of the central plate.

19. The method of production according to claim 17 wherein the forming process for the array comprises forming a first array plate that comprises multiple straight mutually parallel first wall sections and forming a second array plate that comprises multiple mutually straight parallel second wall sections, and forming a central plate with multiple coolant passages, and sandwiching the central plate between the first and second array plates, wherein the method comprises providing the first wall sections angled relatively to the second wall sections such that the first and second wall sections are crossed relatively to each when projected onto the central plate, wherein each first and second wall sections forms flow path segments in combination with the passages form the helical or quasi-helical flow path of the coolant through the cavity, wherein each of the multiple passages in the central plate is connecting one of the first flow path segments formed by the first wall sections on a first side of the central plate to one of the second flow segments formed by the second wall sections on the second, opposite side of the central plate; wherein the flow segments are arranged alternating between the first and second side of the central plate for flow of coolant alternatingly between the first and the second side of central plate, with a first flow path segment along one of the first wall sections on the first side of the central plate, then through the central plate and then along one of the second straight wall sections on the second side of the central plate before flowing back again to the first side through central sectional plane for similar consecutive flow path segments, resembling a quasi-helical flow path.
